(19) United States
(12) Patent Application Publication
(10) Pub. No.: US 2022/0388117 A1
(43) Pub. Date: Dec. 8, 2022

(54) POLISHING PAD SURFACE COOLING BY COMPRESSED GAS

(71) Applicant: Revasum, Inc., San Luis Obispo, CA (US)

(72) Inventors: Robert Lewis Rhoades, Arroyo Grande, CA (US); Bryan Francis Sennett, San Luis Obispo, CA (US); Peter Sterling Patrick Vowell, San Luis Obispo, CA (US)

(21) Appl. No.: 17/337,298

(22) Filed: Jun. 2, 2021

(51) Int. Cl. B24B 55/02; B24B 53/017; H01L 21/3105; H01L 21/321

(52) U.S. Cl. CPC B24B 55/02; B24B 53/017; H01L 21/31053; H01L 21/3212

(57) ABSTRACT

The present disclosure describes an apparatus for chemical-mechanical polishing of a semiconductor wafer. Some embodiments of the present disclosure include a pad, a slurry introduction mechanism, a wafer carrier (e.g., carrying a wafer being polished by the chemical-mechanical polishing system), a pad conditioner, and a pad cooling mechanism. The pad cooling mechanism of the present disclosure may apply a liquid or gas to the pad (e.g., to an upper surface of the pad) to control the temperature of the pad as the chemical-mechanical polishing process occurs. As a result, the temperature of the pad may be maintained at a safe and operable level for an extended period of time during chemical-mechanical polishing of a wafer.

### BACKGROUND OF THE INVENTION

### 1. Field of the Invention

The present invention relates generally to polishing, and more specifically to chemical-mechanical polishing.

### 2. Discussion of the Related Art

Various systems and processes are known in the art for chemical-mechanical polishing.

Chemical mechanical polishing or planarization (CMP) is a technique of polishing materials. For example, semiconductor substrates and films overlying such substrates may be polished using techniques such as CMP, as CMP may provide a high degree of planarity and uniformity. Such polishing techniques may be used to remove layers of film, to reveal the circuitry buried underneath film, to remove high elevation features on films created during the fabrication of a microelectronic circuitry on the substrate, etc. In some cases, polishing techniques such as CMP can be implemented to planarize semiconductor slices (e.g., wafers) prior to the fabrication of microelectronic circuitry thereon.

Some conventional polishing techniques use an apparatus having a single large polishing pad positioned on a table (e.g., a platen), and a substrate may be positioned against the table for polishing. A positioning member (e.g., a wafer carrier) positions and biases the substrate to be polished against the polishing pad. The polishing pad may be rotated, thus polishing the substrate. In some examples, a slurry (e.g., a chemical slurry), which is likely to have abrasive materials, may be maintained on the rotating polishing pad to modify the polishing characteristics of the polishing pad and to enhance the polishing of the substrate or films.

### SUMMARY

The present disclosure describes an apparatus for chemical-mechanical polishing of a semiconductor wafer. Some embodiments of the present disclosure include a pad, a slurry introduction mechanism, a wafer carrier (e.g., carrying a wafer being polished by the chemical-mechanical polishing system), a pad conditioner, and a pad cooling mechanism. The pad cooling mechanism of the present disclosure may apply a liquid or gas to the pad (e.g., to an upper surface of the pad) to control the temperature of the pad as the chemical-mechanical polishing process occurs. As a result, the temperature of the pad may be maintained at a safe and operable level for an extended period of time during chemical-mechanical polishing of a wafer.

An apparatus, system, and method for chemical-mechanical polishing are described. One or more embodiments of the apparatus, system, and method include a first motor, a platen having a first rotational axis and being coupled to the first motor configured to rotate in response to rotation of the first motor, a polishing pad on an upper surface of the platen, a wafer carrier, positioned adjacent to and above the polishing pad and configured to position a wafer over and in contact with the polishing pad, and having a second rotational axis, wherein the first motor rotates the platen relative to the wafer carrier, a nozzle directed to an upper surface of the polishing pad, and a gas supply coupled to the nozzle configured to supply gas to the nozzle, wherein the nozzle directs a stream of the gas to the upper surface of the polishing pad.

A method, apparatus, non-transitory computer readable medium, and system for chemical-mechanical polishing are described. One or more embodiments of the method, apparatus, non-transitory computer readable medium, and system include providing a first motor, providing a platen coupled to the first motor having a first rotational axis and a first diameter, and having a first circumference, providing a polishing pad on an upper surface of the platen, providing a wafer carrier, positioned adjacent to and above the polishing pad and configured to position a wafer over and in contact with the polishing pad, and having a second rotational axis and a second diameter that is smaller than the first diameter, wherein the first motor rotates the platen relative to the wafer carrier, providing a nozzle directed to an upper surface of the polishing pad, rotating, in response to rotation of the first motor, the platen, and supplying gas to the nozzle via a gas supply, wherein the nozzle directs a stream of the gas to the upper surface of the polishing pad.

### BRIEF DESCRIPTION OF THE DRAWINGS

FIG. 1 shows an example of a chemical-mechanical polisher according to aspects of the present disclosure.

FIGS. 2 through 3 show examples of a top view of a chemical-mechanical polisher according to aspects of the present disclosure.

FIG. 4 shows an example of a pad cooling mechanism according to aspects of the present disclosure.

FIG. 5 shows an example of an exploded view of a pad cooling mechanism according to aspects of the present disclosure.

FIG. 6 shows an example of a pad cooling mechanism cross-section according to aspects of the present disclosure.

FIGS. 7 through 8 show examples of a process for chemical-mechanical polishing according to aspects of the present disclosure.

### DETAILED DESCRIPTION

The following description is not to be taken in a limiting sense, but is made merely for the purpose of describing the general principles of exemplary embodiments. The scope of the invention should be determined with reference to the claims.

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art will recognize, however, that the invention can be practiced without one or more of the specific details, or with other methods, components, materials, and so forth. In other instances, well-known structures, materials, or operations are not shown or described in detail to avoid obscuring aspects of the invention.

Chemical mechanical polishing or planarization (CMP) is a technique of polishing materials. For example, semiconductor substrates and films overlying such substrates may be polished using techniques such as CMP, as CMP may provide a high degree of planarity and uniformity. Such polishing techniques may be used to remove layers of film, to reveal the circuitry buried underneath film, to remove high elevation features on films created during the fabrication of a microelectronic circuitry on the substrate, etc. In some cases, polishing techniques such as CMP can be implemented to planarize semiconductor slices (e.g., wafers) prior to the fabrication of microelectronic circuitry thereon.

Some conventional polishing techniques use an apparatus having a single large polishing pad positioned on a table (e.g., a platen), and a substrate may be positioned against the table for polishing. A positioning member (e.g., a wafer carrier) positions and biases the substrate to be polished against the polishing pad. The polishing pad may be rotated, thus polishing the substrate. In some examples, a slurry (e.g., a chemical slurry), which is likely to have abrasive materials, may be maintained on the rotating polishing pad to modify the polishing characteristics of the polishing pad and to enhance the polishing of the substrate or films.

However, polishing of substrates and deposited films may generate varying amounts of heat at the polishing interface (e.g., at the polishing interface between the wafer or substrate being polished and the top surface of the polishing pad). In some cases, there is a significant amount of heat generated during such polishing due to the pressures, speeds, and chemical reactions involved. In some examples, such generated heat may cause the pad surface temperature to rise high enough to have deleterious effects on pad life. For instance, in some cases, the polishing pad may have low thermal conductivity, and heat dissipation into the polishing pad may not be efficient.

Some polishing systems may include techniques for actively chilling the platen for the table where the pad is adhered, however the ability to dissipate heat from the pad surface is limited due to the thickness and low thermal conductivity of the pad, as the pad may comprise polymers (e.g., filled urethanes, non-woven polyester fibers, and the like). Additionally or alternatively, liquid slurry mixture supplied to the pad may be chilled to provide some amount of cooling for the process, however in some cases such techniques may also result in inadequate cooling. For instance, the inability to reduce the slurry temperature before impacting the colloidal stability of the slurry, the reduced activity of the chemical ingredients at lower slurry temperatures, and the small heat capacity of slurry at low delivery flows when compared to the very large thermal mass of the pad sitting on a polishing platen or table may contribute the inadequate cooling.

Embodiments of the present disclosure include a pad cooling mechanism (e.g., including a gas supply and one or more nozzles) fed by a compressed gas supply to cool the surface (e.g., and upper surface) of a polishing pad. For example, a pad cooling mechanism may include a gas supply and one or more nozzles for directing gas (e.g., clean dry air, pressurized nitrogen, etc.) to the surface of the polishing pad (e.g., during CMP). In some examples, a pad cooling mechanism may be integrated with a slurry introduction mechanism (e.g., a slurry distribution arm) into a single arm structure. In other examples, a pad cooling mechanism may be implemented as a standalone structure (e.g., as a separate arm from the slurry introduction mechanism).

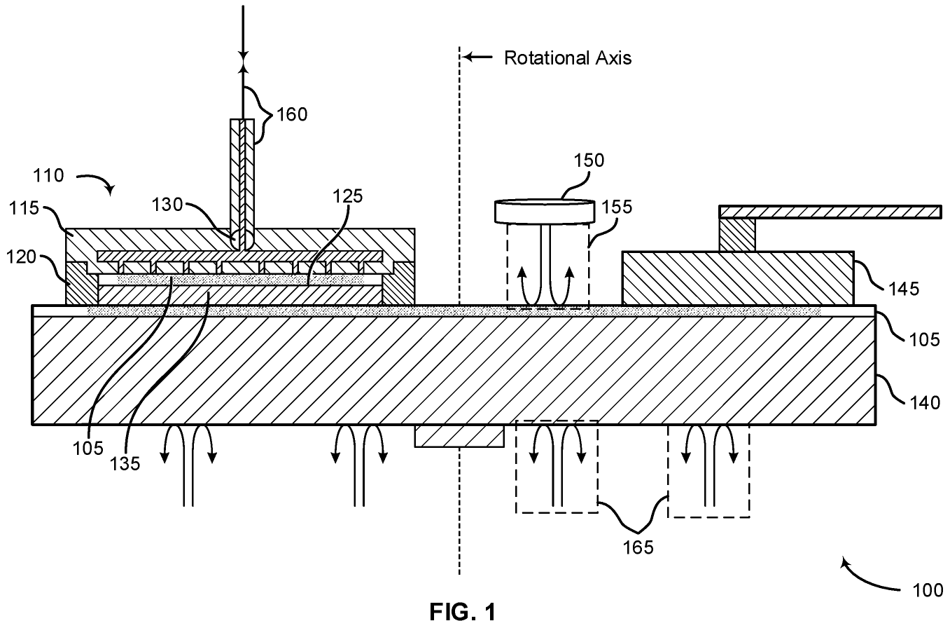

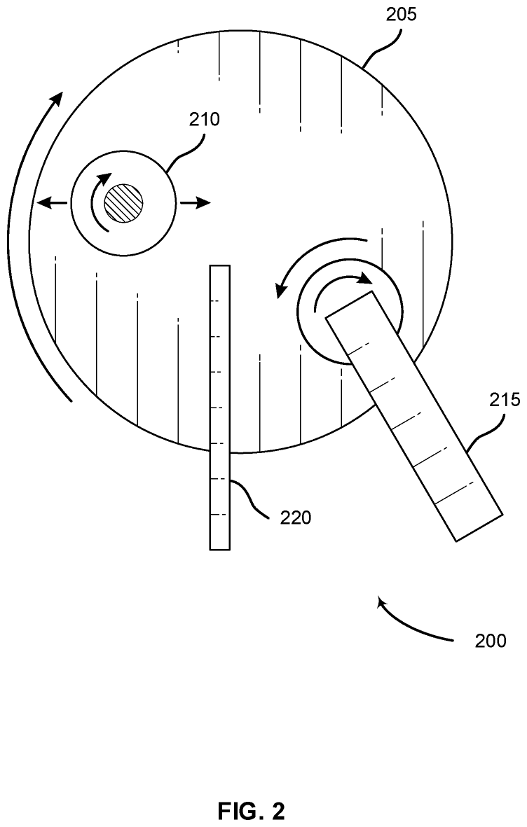

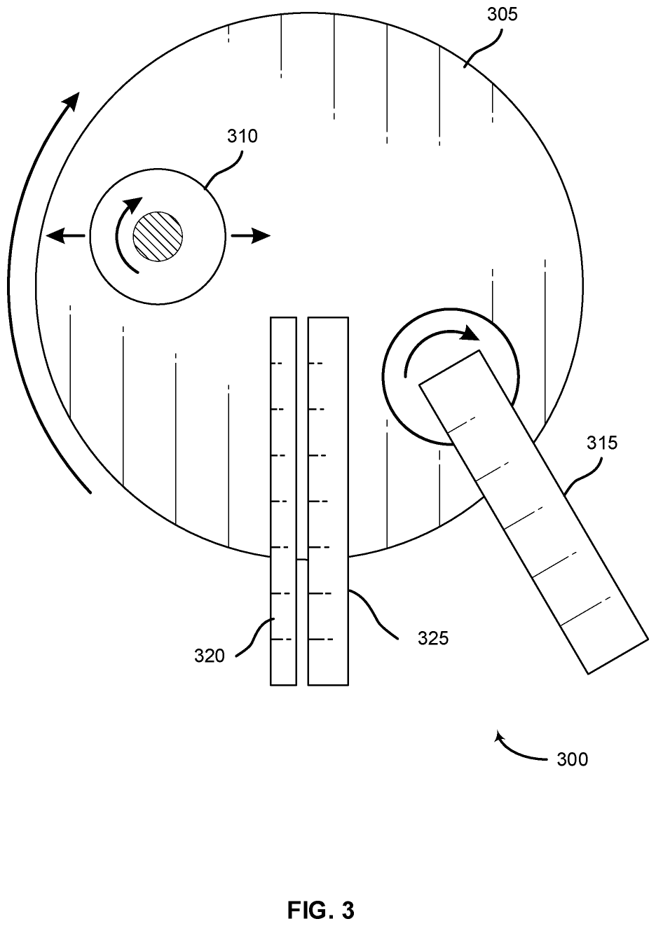

FIG. 1 shows an example of a chemical-mechanical polisher 100 according to aspects of the present disclosure. Chemical-mechanical polisher 100 is an example of, or includes aspects of, the corresponding element described with reference to FIGS. 2 and 3. In one embodiment, chemical-mechanical polisher 100 includes pad 105, wafer carrier 110, wafer 135, platen 140, pad conditioner 145, slurry introduction mechanism 150, back pressure or vacuum 160, and platen heating/cooling mechanism 165.

A chemical-mechanical polisher 100 is a device used to smooth and planarize (flatten) a wafer 135 in the semiconductor manufacturing process. Both a chemical-etching compound and mechanical forces are used to provide a smooth and flat finish of the wafer 135. In some cases, an abrasive pad 105 (i.e., polishing pad 105) is used to apply a level of grit to the wafer 135, where the wafer 135 is held in place by the wafer carrier 110. Further, a chemical such as potassium permanganate with nitric acid is applied to the pad 105 for additional smoothing.

According to some embodiments, wafer carrier 110 is positioned adjacent to and above the polishing pad 105 and configured to position a wafer 135 over and in contact with the polishing pad 105, and having a second rotational axis, wherein the first motor rotates the platen 140 relative to the wafer carrier 110. In some examples, the wafer carrier 110 has a second diameter that is smaller than the first diameter.

Wafer carrier 110 is an example of, or includes aspects of, the corresponding element described with reference to FIGS. 2 and 3. In one embodiment, wafer carrier 110 includes carrier housing 115, retaining ring 120, backing film 125, and gimbal point 130.

A motor is an electro-mechanical device used to rotate or move a component. In some cases, the motor of the present disclosure rotates the platen, pad, or table of the chemical-mechanical polisher and may pivot or move the pad conditioner, slurry introduction mechanism, and pad cooling mechanism.

A wafer 135, or semiconductor wafer 135, is a thin piece of semiconductor material used in the creation of, for example, an integrated circuit. In some cases, the wafer 135 is a substrate for microelectronics, such as transistors, to be built on the wafer 135.

The wafer carrier 110 contains the wafer 135 in such a fashion to maintain a secure fitting of the wafer 135 against the pad 105. The wafer 135 is mounted face down in the wafer housing 115 and is pressed against the pad 105 with a specified force. This force can be provided using either a defined and regulated gas pressure or a mechanical backing pressure system.

A retaining ring 120 surrounds the wafer 135, circumferentially, providing a radial force on the wafer 135. This radial force supports the wafer 135 in place. In some cases, the retaining ring 120 functions in conjunction with a pressure system to apply an axial force against polish pad 105, which prevents the wafer 135 from moving.

Backing film 125 contacts the back of the wafer 135 and is affixed to a pad 105 surface, which may face the wafer 135. The backing film 125 serves as a cushion against the asperity of the pad 105 surface and wafer housing 115 surfaces.

A gimbal point 130 connects a wafer 135 housing to the chemical-mechanical polisher 100. In some cases, the gimbal point 130 may be pivotally connected or a solid connection.

A back pressure or vacuum 160 may be implemented in a chemical-mechanical polisher 100 system to keep a wafer 135 in place on top of a pad 105 by applying an axial load to the wafer 135. In some cases, the back pressure or vacuum 160 may include pressure control products to be applied to the system for controlling the backing pressure applied to the wafer 135 holder. Pressure or flow controllers can be used with different gas flow control valves to control the backing gas pressure on wafer 135 housings in chemical-mechanical polishing tools.

A pad conditioner 145 is attached to a secondary arm, above the platen 140 and pad 105, and is used to clean the surface of the pad 105 of impurities or irregularities. In some cases, the pad conditioner 145 may be a diamond studded disk and a chemical compound or liquid may be applied to the pad 105 while conditioning. Pad conditioner 145 is an example of, or includes aspects of, the corresponding element described with reference to FIGS. 2 and 3.

A pad 105, or polishing pad 105, is a piece of gritty, semi-gritty material, urethane, or felt-like material applied to a rotating platen 140, used for flattening or polishing a semiconductor wafer 135. In some cases, the pad 105 may be a piece of stone like material (i.e., silicon carbide or aluminum oxide) or sandpaper. According to some embodiments, a polishing pad 105 is provided on an upper surface of the platen 140. Pad 105 is an example of, or includes aspects of, the corresponding element described with reference to FIGS. 2 and 3.

In semiconductor manufacturing or etching processes, a platen 140 is a plate used to flatten and polish a wafer 135. The platen 140 is attached to a motor and is rotated around a center axis. A polishing pad 105 is then attached to the platen 140. A wafer 135 is applied to the upper surface of the platen 140 and is polished as the platen 140 rotates.

A platen heating/cooling mechanism 165 may apply a fluid such as gas or liquid to the back side of the platen 140 to maintain a predetermined temperature. Platen heating/cooling mechanism 165 may actively chill the platen (e.g., for the table where the pad is adhered, but the platen heating/cooling mechanism 165 may not necessarily dissipate heat from the pad surface itself).

Chemical-mechanical polishing is a metrological planarization technique developed for semiconductor applications. Over time, the number of metal layers has increased, and device topographies have features that inhibited conformal deposition and gap-fill by photoresist, metal, and insulator films.

A fully conformal film exhibits a ratio of 1:1 for the film thickness on planar versus vertical surfaces. Conformal films can fill the spaces between features such as metal lines, and non-conformal films can result in voids in the insulating layers. The voids are electrical weak spots that can result in device failure. As the severity of device topographies has increased, many variations of chemical vapor deposition process technology may be used to improve the conformal characteristics of insulating films. Eventually, however, the increase in the number of metal layers and more severe topographies forced device manufacturers to move to chemical-mechanical polishing as a planarization method and, within the context of semiconductor device fabrication, the acronym chemical-mechanical polishing refers to chemical-mechanical planarization. Using a complex multi-level metal device structure using non-planarized deposition technology compared to a chemical-mechanical polishing-based planarization may present issues.

Chemical-mechanical planarization is a physical polishing process in which the surface of a substrate (e.g., a wafer 135) is smoothed and planarized through the combined action of chemical and physical abrasive forces on the surface. Whereas abrasive grinding of the surface would cause excessive physical damage and chemical etching would not achieve planarization, the combined action of the two produces a well-planarized surface with minimal damage. A chemical-mechanical planarization tool of the present disclosure includes a rotating platen 140 covered by a polishing pad 105. A wafer 135 is mounted face down in a wafer carrier 110 pressed against the pad 105 with a specified force, where the force can be provided using either a defined and regulated gas pressure or a mechanical backing pressure system. The wafer 135 also rotates during the polishing process. The polishing pad 105 is saturated with a slurry 155 of physical abrasive and chemical etchant pumped onto the pad 105 (e.g., via slurry introduction mechanism 150).

Polishing of the wafer 135 surface occurs as the wafer 135 is rotated and moved about the polishing pad 105 while being forced against the pad 105. During the polishing process, high points on the wafer 135 surface are naturally subjected to more pressure and, therefore a more abrasive force. Combined with the action of the chemical etchant, the polishing process produces an enhanced removal rate for material at the high points relative to material at low points in the surface topography producing the planarization effect in the process. Since heat is generated in the polishing process and changes in temperature effect etch rates, embodiments of the present disclosure maintain a constant temperature at the pad 105/wafer 135 interface during the chemical-mechanical polishing process using active temperature control of the platen 140 and pad 105.

Chemical-mechanical planarization may be used for semiconductor device manufacturing beyond to reduce rough topography to a planarized state. Chemical-mechanical polishing provides planarization of the entire wafer 135 surface in a single step. Embodiments of the present disclosure can be used to planarize a wide range of materials, from different metals to different oxide films and substrates such as silicon carbide, silicon, and sapphire. Additionally, or alternatively, embodiments of the present disclosure can planarize different materials in the same step (i.e., metal and insulating films). Chemical-mechanical polishing is an effective method of copper patterning (i.e., damascene processing.) The subtractive nature of chemical-mechanical polishing helps in reducing surface defects. Finally, the process is relatively environmentally benign, with no hazardous gases commonly used in dry etch processing.

Device speed has become limited by a phenomenon known as RC delays (where R is the resistance of the wiring and C is the capacitance of parasitic capacitors in the circuit structure). Signal transmission on a device is delayed in direct proportion to the resistance of the wire on which the transmission occurs and to the capacitance of any unintended capacitors formed when two metal wires are separated by an insulating material. Reducing the resistance of the wiring may reduce delays. As a result, aluminum or copper wiring may be used, but the present disclosure is not limited thereto, and the wiring may be any metal with electrical or heat conductive properties. Copper has other properties compared to aluminum, such as the dimensions of the wires on a device may shrink, contributing to greater resistance to electromigration.

The use of copper presented serious challenges to device manufacturers. Copper cannot be etched using conventional, halide-based dry etching processes since the copper halide products are not volatile and hence cannot be pumped away by a vacuum system. As a result, the conventional technology for patterning metal lines could not be used with copper. Additionally, copper does not adhere well to dielectric material and copper atoms are very mobile in SiO. Direct deposition of copper on insulating oxide layers thus presented problems in achieving stable wiring structures and in terms of contamination of the insulating oxide (producing increased leakage).

The Damascene (and Dual Damascene) process, first introduced by IBM in the early 1990s, was a unique, additive processing technique developed to address the challenges presented by the shift to copper wiring in microelectronic circuits. The Damascene process eliminates the need to dry etch copper by using chemical-mechanical polishing instead, and using special barrier layers to prevent diffusion of the copper into the oxide insulating layers. The first step in the process is the formation of the wiring pattern as etched lines in a dielectric layer. A barrier layer of, for example, TiN, TaN, or TiW is then deposited on the dielectric layer to act as a barrier between the copper and the insulating dielectric. A thin seed layer of copper is deposited on the barrier, typically using PVD methods, followed by the electrodeposition of a thick copper layer. Chemical-mechanical planarization is then used to remove the excess copper leaving the metal in the etched lines behind.

Pressure control products can be applied to the system to control the backing pressure applied to the wafer carrier 110 (e.g., as shown in FIG. 1 by the back pressure or vacuum system 160). Pressure or flow controllers (e.g., back pressure or vacuum system 160) can be used with different gas flow control valves to control the backing gas pressure on wafer carriers 110 in chemical-mechanical polishing tools.

Chemical-mechanical polishing or planarization is a process of smoothing surfaces with a combination of chemical and mechanical forces, and can be considered a hybrid of chemical etching and free abrasive polishing.

The process uses an abrasive and corrosive chemical slurry 155 (e.g., commonly a colloid) in conjunction with a polishing pad 105 and retaining ring 120, typically of a greater diameter than the wafer 135. The pad 105 and wafer 135 are pressed together by a dynamic polishing wafer carrier 110 and held in place by a plastic retaining ring 120. The dynamic polishing wafer carrier 110 is rotated with different axes of rotation (i.e., not concentric), removing material to even out any irregular topography, producing a flat or planar wafer 135 so the wafer 135 can be used for, for example, additional circuit elements. For example, chemical-mechanical polishing can bring the entire surface within the depth of field of a photolithography system or selectively remove material based on a position.

Typical chemical-mechanical polishing tools include a flat rotating platen 140 that may be covered by a pad 105. The wafer 135 to be polished is mounted upside-down in a wafer carrier 110 (e.g., or spindle) on a backing film 125. The retaining ring 120 holds the wafer 135 in the correct horizontal position. During the process of loading and unloading the wafer 135 onto the tool, the wafer 135 is held by a vacuum (e.g., a back pressure or vacuum system 160) by the wafer carrier 110. A slurry introduction mechanism 150 deposits the slurry 155 on the pad 105. Both the platen 140 and the wafer carrier 110 are then rotated and the wafer carrier 110 is kept oscillating. A downward pressure (i.e., downforce) is applied to the wafer carrier 110, pushing the wafer carrier 110 against the pad 105, typically the downforce is an average force, but local pressure may be used for the removal mechanisms. The downforce may be an average force, but the present disclosure is not limited thereto. Downforce depends on the contact area, which, in turn, is dependent on the structures of both the wafer 135 and the pad 105.

In some cases, a pad 105 may have a roughness of, for example, 50 μm. Contact is made by asperities (which typically are the high points on the wafer 135) and, as a result, the contact area is a fraction of the wafer 135 area. In chemical-mechanical polishing, the mechanical properties of the wafer 135 may be considered too. If the wafer 135 has a bowed structure, the pressure may be greater on the edges than the center, which causes non-uniform polishing. Pressure can be applied to the wafer 135's backside which will equalize the center-edge differences to compensate for the wafer 135 bow. The pads 105 used in the chemical-mechanical polishing tool should be rigid to uniformly polish the wafer 135 surface. However, the rigid pads 105 may be kept in alignment with the wafer 135. Therefore, pads 105 are often stacks of soft and hard materials that conform to wafer 135 topography to some extent. Generally, the pads 105 are made from porous polymeric materials with a pore size between 30-50 μm. Because the pads 105 are consumed in the process, the pads 105 are regularly reconditioned. In some cases, the pads 105 are proprietary and are referred to by trademark names rather than chemical or other properties.

Chemical-mechanical polishing or planarization is a process of smoothing surfaces with a combination of chemical and mechanical forces and can be considered a hybrid of chemical etching and free abrasive polishing.

Chemical-mechanical polishing may be considered to be too dirty to be included in high-precision fabrication processes since abrasion tends to create particles and the abrasives may include impurities. As a result, the integrated circuit industry has moved from aluminum to copper conductors, leading to the use of additive patterning processes, which uses chemical-mechanical polishing to remove material in a planar and uniform fashion and to stop repeatably at the interface between copper and oxide insulating layers. Therefore, chemical-mechanical polishing processing is a more widespread technique. In addition to aluminum and copper, chemical-mechanical polishing processes have been developed for polishing tungsten, silicon dioxide, and carbon nanotubes.

Chemical-mechanical planarization is employed in different planarization applications during device fabrication. Oxide planarization may be used for shallow trench isolation and Damascene processing.

Shallow trench isolation may use trenches etched into the substrate (e.g., wafer 135) and filled with undoped chemical vapor deposition polysilicon or chemical vapor deposition silicon dioxide as electrical isolation for the active regions in a device. Shallow trench isolation has replaced the use of thermal oxide for local oxidation of silicon (LOCOS) due to reasons related to thermal budget and the localized physical impacts of thermal oxidation of silicon. Chemical-mechanical polishing is used in the next to last and last steps of the shallow trench isolation process sequence. Following the deposition of the insulating oxide that fills the isolating trenches, chemical-mechanical polishing is used to planarize the oxide level with the nitride layer. In the last steps of the process, the nitride layer is removed, followed by planarization of the chemical vapor deposition oxide in the trenches. Shallow trench isolation process technology has been one of the enablers of nanometer-scale device fabrication owing to the fact that earlier LOCOS isolation schemes could not be successfully scaled down to the nanometer regime.

Shallow trench isolation, a process used to fabricate semiconductor devices, is a technique used to enhance the isolation between devices and active areas. Moreover, shallow trench isolation has a higher degree of planarity, and is used in photolithographic applications. Additionally, or alternatively, shallow trench isolation may be used for a depth of focus budget by decreasing minimum line width. A method such as the combination of resist etching-back and chemical-mechanical polishing can be used to planarize shallow trenches. As a result, a sequence pattern may be used. First, the isolation trench pattern is transferred to the silicon wafer 135. Oxide is deposited on the wafer 135 in the shape of trenches. A photomask, composed of silicon nitride, is patterned on the top of the oxide. A second layer is added to the wafer 135 to create a planar surface. After that, the silicon is thermally oxidized, so the oxide grows in regions where there is no Si3N4 and the growth is between 0.5 and 1.0 μm thick. Since the oxidizing species such as water or oxygen are unable to diffuse through the mask, the nitride prevents the oxidation. Next, the etching process is used to etch the wafer 135 and leave a small amount of oxide in the active areas. In the end, chemical-mechanical polishing is used to polish the SiO₂ overburden with an oxide on the active area.

According to some embodiments, wafer carrier 110 provides a wafer carrier 110, positioned adjacent to and above the polishing pad 105 and configured to position a wafer 135 over and in contact with the polishing pad 105, and having a second rotational axis and a second diameter that is smaller than the first diameter, where the first motor rotates the platen 140 relative to the wafer carrier 110.

According to some embodiments, platen 140 has a first rotational axis and being coupled to the first motor configured to rotate in response to rotation of the first motor. In some examples, the platen 140 has a first diameter and a first circumference. According to some embodiments, platen 140 is coupled to the first motor having a first rotational axis and a first diameter, and having a first circumference.

According to some embodiments, slurry introduction mechanism 150 deposits (e.g., applies, supplies, etc.) a slurry 155 on the upper surface of the polishing pad 105. According to some embodiments, slurry introduction mechanism 150 provides a slurry introduction mechanism 150. In some examples, slurry introduction mechanism 150 deposits a slurry 155 on the upper surface of the polishing pad 105. Slurry introduction mechanism 150 is an example of, or includes aspects of, the corresponding element described with reference to FIGS. 2 and 3. In one embodiment, slurry introduction mechanism 150 includes slurry 155 (e.g., and slurry introduction mechanism 150 applies slurry to an upper surface of polishing pad 105).

FIG. 2 shows an example of a top view of a chemical-mechanical polisher 200 according to aspects of the present disclosure. Chemical-mechanical polisher 200 is an example of, or includes aspects of, the corresponding element described with reference to FIGS. 1 and 3. In one embodiment, chemical-mechanical polisher 200 includes pad 205, wafer carrier 210, pad conditioner 215, and slurry introduction mechanism 220.

Pad 205 is an example of, or includes aspects of, the corresponding element described with reference to FIGS. 1 and 3. Wafer carrier 210 is an example of, or includes aspects of, the corresponding element described with reference to FIGS. 1 and 3. Pad conditioner 215 is an example of, or includes aspects of, the corresponding element described with reference to FIGS. 1 and 3. Slurry introduction mechanism 220 is an example of, or includes aspects of, the corresponding element described with reference to FIGS. 1 and 3.

A slurry introduction mechanism 220 (e.g., a slurry arm, slurry supply, etc.) may be pivotally connected to the chemical-mechanical polisher 200 and has a slurry delivery system that may be translatable along the length of the slurry introduction mechanism 220. As a result, the system may deposit polishing slurry at a desired location on the polishing pad 205 of the chemical-mechanical polisher 200.

Polishing of substrates and deposited films generates varying amounts of heat at the polishing interface between the surface being polished and the top surface of the polishing pad 205. In some cases, such as silicon crystalline (SiC) substrate polishing, there is a significant amount of heat due to the pressures, speeds, and chemical reactions involved which can cause the pad 205 surface temperature to rise high enough to have deleterious effects on pad 205 life. For instance, in some cases, the polishing pad 205 may have low thermal conductivity, and heat dissipation into the polishing pad 205 may not be efficient.

FIG. 3 shows an example of a top view of a chemical-mechanical polisher 300 according to aspects of the present disclosure. Chemical-mechanical polisher 300 is an example of, or includes aspects of, the corresponding element described with reference to FIGS. 1 and 2. In one embodiment, chemical-mechanical polisher 300 includes pad 305, wafer carrier 310, pad conditioner 315, slurry introduction mechanism 320, and pad cooling mechanism 325.

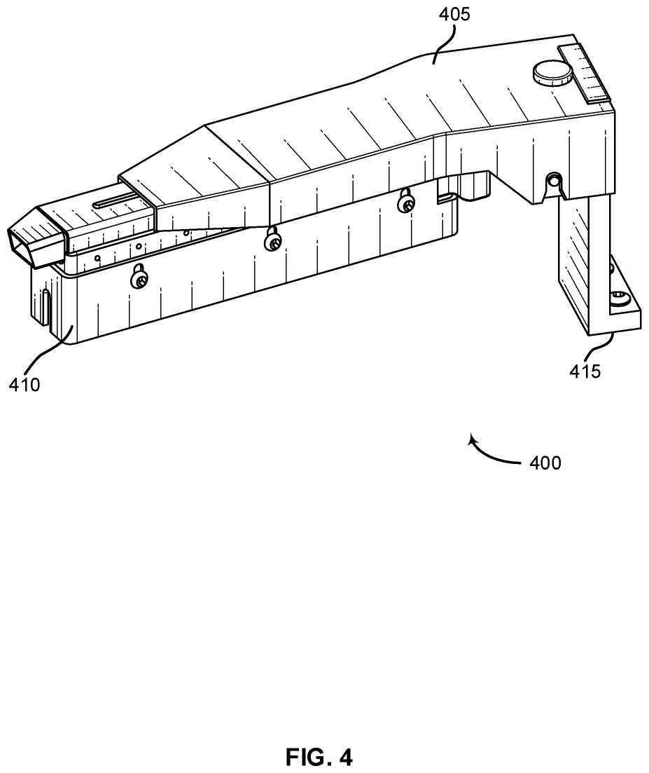

Pad 305 is an example of, or includes aspects of, the corresponding element described with reference to FIGS. 1 and 2. Wafer carrier 310 is an example of, or includes aspects of, the corresponding element described with reference to FIGS. 1 and 2. Pad conditioner 315 is an example of, or includes aspects of, the corresponding element described with reference to FIGS. 1 and 2. Slurry introduction mechanism 320 is an example of, or includes aspects of, the corresponding element described with reference to FIGS. 1 and 2. Pad cooling mechanism 325 is an example of, or includes aspects of, the corresponding element described with reference to FIGS. 4-6.

The pad cooling mechanism 325 includes one or more directional nozzles, which may be aimed downward at the surface of the pad 305. The pad cooling mechanism 325 applies a cooling or heating fluid, such as gas or liquid, to the surface of the pad 305 to maintain a predetermined temperature of the pad 305 and platen. In some cases, the pad cooling mechanism 325 is located immediately after the slurry introduction mechanism or the wafer housing, as the present disclosure is not limited to the location of the pad cooling mechanism 325.

The support arm attaches the nozzle housing to the chemical-mechanical polisher 300. In some cases, the support arm may be pivotally attached to the periphery of the chemical-mechanical polisher 300. The nozzle may include a gas supply.

A slurry, or slurry compound, may include a physically abrasive or chemical etchant applied to the pad 305. As the pad 305 rotates, the pad 305 continuously applies the slurry to the wafer. In some examples, slurry may be supplied to (e.g., and maintained on) the polishing pad 305 to modify the polishing characteristics of the polishing pad 305 and to enhance the polishing of the wafer, substrate, or films.

Embodiments of the present disclosure use one or more directional nozzles located behind the trailing edge of a carrier to aim the nozzles downward at a surface of the polishing pad 305. The nozzle can be fed by compressed clean dry air (CDA), or pressurized nitrogen, or any other convenient gas that can be provided at a controlled pressure to the system. Gas flow through the nozzle should be controlled by one or more valves which may be timed relative to the polishing cycle to minimize wasted gas during idle periods when substrates are not being polished. The nozzle or nozzles should be located some distance above the pad 305 and can have a variety of dispersal patterns. Nozzles can be singular or plural orifice and each orifice can be shaped as desired to affect the desired dispersal pattern of the gas. The pressure and velocity of the gas at the pad 305 surface may be sufficient to provide cooling but not high enough to create flash drying of the slurry. A broad operating range may be used to adjust the pad 305 surface cooling effect based on slurry properties, amount of heat being generated in a particular application, etc.

According to techniques described herein, polishing methods (e.g., chemical-mechanical polishing systems) may implement active cooling, for example, for the top surface of a pad 305. As described in more detail herein (e.g., with reference to FIGS. 4-6), embodiments of the present disclosure include a pad cooling mechanism 325 (e.g., including one or more nozzles) fed by a compressed gas supply to cool the surface of a polishing pad 305.

Embodiments of the present disclosure may be used in, for example, SiC stock removal chemical-mechanical polishing or any polishing application that generates an elevated pad 305 surface temperature. For example, polishing of SiC and other hard substrates such as sapphire, GaN, quartz, and the like may be performed. Embodiments of the present disclosure also include deposited or grown films of such materials on virtually any other substrate, bonded stacks of such materials, or patterned composites where a part of the exposed surface is comprised of such materials. Embodiments of the present disclosure may also be used for polishing of materials with slurries that include exothermic chemical reactions in their functionality. As a result, the mechanical properties of the material being polished may be different, but embodiments of the present disclosure have the ability to dissipate heat from the polishing interface.

In some examples, pad cooling mechanism 325 may be placed a first distance (e.g., a few inches) above the polishing pad 305 and may be directed towards the polishing pad 305 a second distance (e.g., about 2 inches) behind the trailing edge of the wafer carrier 310 (e.g., for a SiC polishing process).

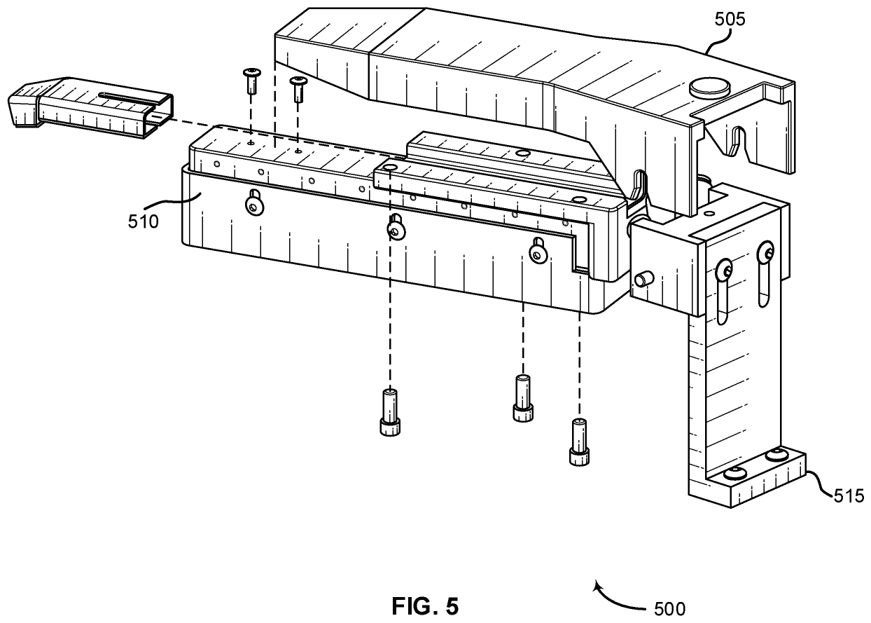

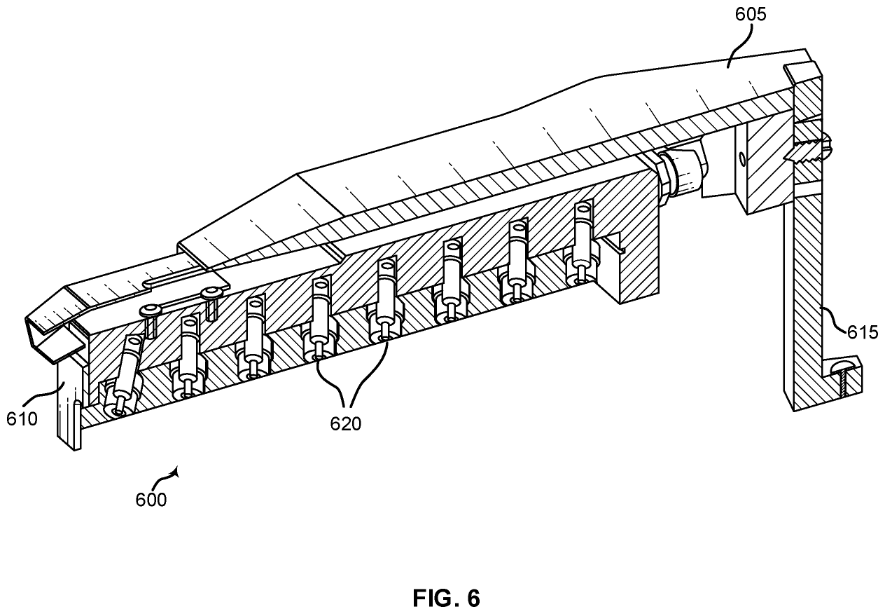

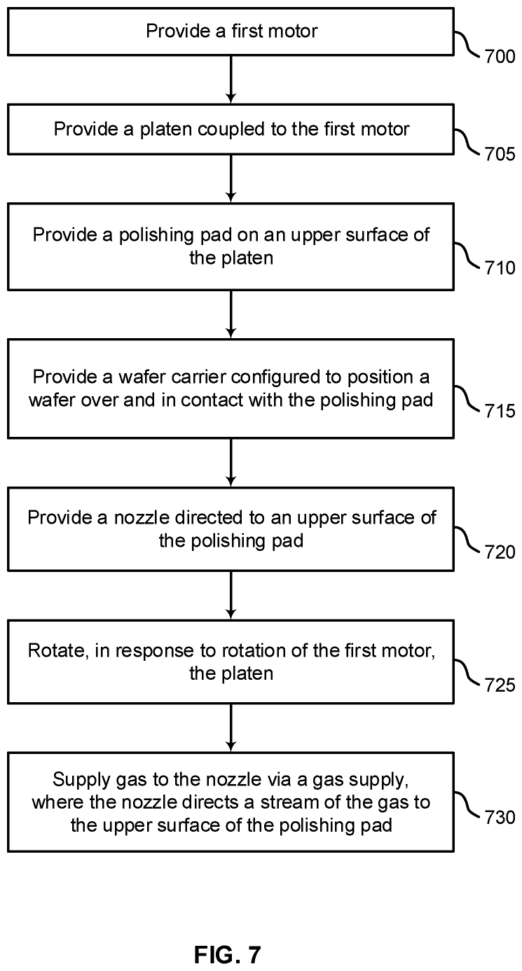

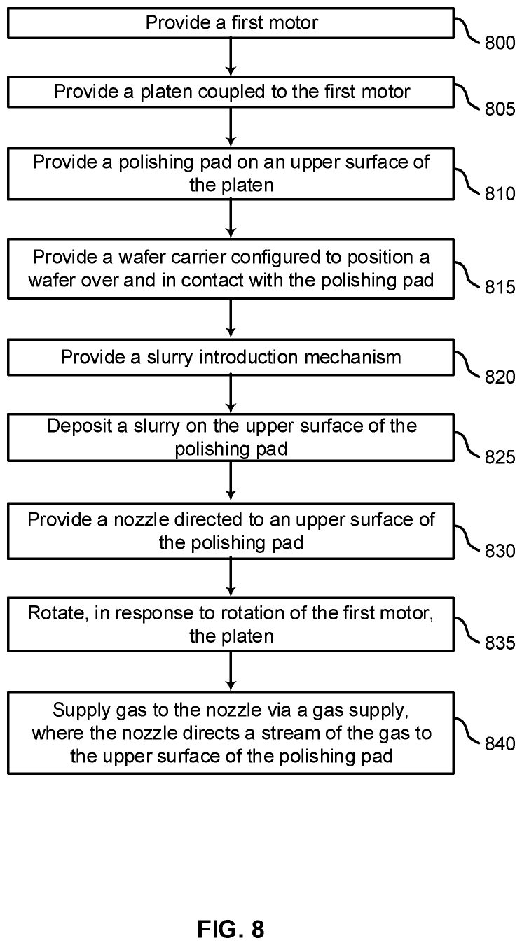

FIG. 4 shows an example of a pad cooling mechanism 400 according to aspects of the present disclosure. Pad cooling mechanism 400 is an example of, or includes aspects of, the corresponding element described with reference to FIGS. 3, 5, and 6. In one embodiment, pad cooling mechanism 400 includes arm cover 405, nozzle housing 410, and support arm 415. Nozzle housing 410 is an example of, or includes aspects of, the corresponding element described with reference to FIGS. 5 and 6. Support arm 415 is an example of, or includes aspects of, the corresponding element described with reference to FIGS. 5 and 6.

The arm cover 405 surrounds the pad cooling mechanism 400 to protect the pad cooling mechanism 400 and support it over pad 305. The nozzle housing 410 includes one or more nozzles used to supply the pad with the fluid. In some cases, the nozzle housing 410 fully surrounds the nozzles, or partially surrounds the nozzles.

FIG. 5 shows an example of an exploded view of a pad cooling mechanism 500 according to aspects of the present disclosure. Pad cooling mechanism 500 is an example of, or includes aspects of, the corresponding element described with reference to FIGS. 3,4 and 6. In one embodiment, pad cooling mechanism 500 includes arm cover 505, nozzle housing 510, and support arm 515.

Arm cover 505 is an example of, or includes aspects of, the corresponding element described with reference to FIG. 6. Nozzle housing 510 is an example of, or includes aspects of, the corresponding element described with reference to FIGS. 4 and 6. Support arm 515 is an example of, or includes aspects of, the corresponding element described with reference to FIGS. 4 and 6.

FIG. 6 shows an example of a pad cooling mechanism 600 cross-section according to aspects of the present disclosure. Pad cooling mechanism 600 is an example of, or includes aspects of, the corresponding element described with reference to FIGS. 3, 4, and 5. In one embodiment, pad cooling mechanism 600 includes arm cover 605, nozzle housing 610, and support arm 615.

Arm cover 605 is an example of, or includes aspects of, the corresponding element described with reference to FIG. 5. Nozzle housing 610 is an example of, or includes aspects of, the corresponding element described with reference to FIGS. 4 and 5. Support arm 615 is an example of, or includes aspects of, the corresponding element described with reference to FIGS. 4 and 5, and one or more nozzles 620.

The one or more nozzles 620 supply fluid (e.g., cooling fluid, such as a liquid or gas) to the pad. The nozzle can be fed by compressed clean dry air (CDA), or pressurized nitrogen, or any other convenient gas that can be provided at a controlled pressure to the system. Gas flow through the nozzle should be controlled by one or more valves which may be timed relative to the polishing cycle to minimize wasted gas during idle periods when substrates are not being polished. The nozzle or nozzles 620 should be located some distance above the pad and can have a variety of dispersal patterns. Nozzles 620 can be singular or plural orifice and each orifice can be shaped as desired to affect the desired dispersal pattern of the gas. The pressure and velocity of the gas at the pad surface may be sufficient to provide cooling but not high enough to create flash drying of the slurry. A broad operating range may be used to adjust the pad surface cooling effect based on slurry properties, amount of heat being generated in a particular application, etc.

FIG. 5 shows an example of a process for chemical-mechanical polishing according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

At operation 700, the system provides a first motor. In some cases, the operations of this step refer to, or may be performed by, a motor as described with reference to FIG. 1.

At operation 705, the system provides a platen coupled to the first motor having a first rotational axis and a first diameter, and having a first circumference. In some cases, the operations of this step refer to, or may be performed by, a platen as described with reference to FIG. 1.

At operation 710, the system provides a polishing pad on an upper surface of the platen. In some cases, the operations of this step refer to, or may be performed by, a pad as described with reference to FIGS. 1-3.

At operation 715, the system provides a wafer carrier, positioned adjacent to and above the polishing pad and configured to position a wafer over and in contact with the polishing pad, and having a second rotational axis and a second diameter that is smaller than the first diameter, where the first motor rotates the platen relative to the wafer carrier. In some cases, the operations of this step refer to, or may be performed by, a wafer carrier as described with reference to FIGS. 1-3.

At operation 720, the system provides a nozzle directed to an upper surface of the polishing pad. In some cases, the operations of this step refer to, or may be performed by, a nozzle as described with reference to FIGS. 3,4 and 6.

At operation 725, the system rotates, in response to rotation of the first motor, the platen. In some cases, the operations of this step refer to, or may be performed by, a motor as described with reference to FIG. 1.

At operation 730, the system supplies gas to the nozzle via a gas supply, where the nozzle directs a stream of the gas to the upper surface of the polishing pad. In some cases, the operations of this step refer to, or may be performed by, a gas supply as described with reference to FIG. 3.

FIG. 6 shows an example of a process for chemical-mechanical polishing according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

At operation 800, the system provides a first motor. In some cases, the operations of this step refer to, or may be performed by, a motor as described with reference to FIG. 1.

At operation 805, the system provides a platen coupled to the first motor having a first rotational axis and a first diameter, and having a first circumference. In some cases, the operations of this step refer to, or may be performed by, a platen as described with reference to FIG. 1.

At operation 810, the system provides a polishing pad on an upper surface of the platen. In some cases, the operations of this step refer to, or may be performed by, a pad as described with reference to FIGS. 1-3.

At operation 815, the system provides a wafer carrier, positioned adjacent to and above the polishing pad and configured to position a wafer over and in contact with the polishing pad, and having a second rotational axis and a second diameter that is smaller than the first diameter, where the first motor rotates the platen relative to the wafer carrier. In some cases, the operations of this step refer to, or may be performed by, a wafer carrier as described with reference to FIGS. 1-3.

At operation 820, the system provides a slurry introduction mechanism. In some cases, the operations of this step refer to, or may be performed by, a slurry introduction mechanism as described with reference to FIGS. 1-3.

At operation 825, the system deposits a slurry on the upper surface of the polishing pad. In some cases, the operations of this step refer to, or may be performed by, a slurry introduction mechanism as described with reference to FIGS. 1-3.

At operation 830, the system provides a nozzle directed to an upper surface of the polishing pad. In some cases, the operations of this step refer to, or may be performed by, a nozzle as described with reference to FIGS. 3 and 6.

At operation 835, the system rotates, in response to rotation of the first motor, the platen. In some cases, the operations of this step refer to, or may be performed by, a motor as described with reference to FIG. 1.

At operation 840, the system supplies gas to the nozzle via a gas supply, where the nozzle directs a stream of the gas to the upper surface of the polishing pad. In some cases, the operations of this step refer to, or may be performed by, a gas supply as described with reference to FIGS. 3 and 6.

Accordingly, the present disclosure includes the following embodiments.

An apparatus for chemical-mechanical polishing is described. One or more embodiments of the apparatus include a first motor, a platen having a first rotational axis and being coupled to the first motor configured to rotate in response to rotation of the first motor, a polishing pad on an upper surface of the platen, a wafer carrier, positioned adjacent to and above the polishing pad and configured to position a wafer over and in contact with the polishing pad, and having a second rotational axis, wherein the first motor rotates the platen relative to the wafer carrier, a nozzle directed to an upper surface of the polishing pad, and a gas supply coupled to the nozzle configured to supply gas to the nozzle, wherein the nozzle directs a stream of the gas to the upper surface of the polishing pad.

A system for chemical-mechanical polishing; the system further comprising: a first motor, a platen having a first rotational axis and being coupled to the first motor configured to rotate in response to rotation of the first motor, a polishing pad on an upper surface of the platen, a wafer carrier, positioned adjacent to and above the polishing pad and configured to position a wafer over and in contact with the polishing pad, and having a second rotational axis, wherein the first motor rotates the platen relative to the wafer carrier, a nozzle directed to an upper surface of the polishing pad, and a gas supply coupled to the nozzle configured to supply gas to the nozzle, wherein the nozzle directs a stream of the gas to the upper surface of the polishing pad.

In some examples, the platen has a first diameter and a first circumference. In some examples, the wafer carrier has a second diameter that is smaller than the first diameter.

Some examples of the apparatus, system, and method described above further include a second nozzle directed to the upper surface of the polishing pad, where the gas supply is coupled to the second nozzle and the second nozzle directs another stream of the gas to the upper surface of the polishing pad.

In some examples, the gas is clean dry air.

In some examples, the gas is pressurized nitrogen.

Some examples of the apparatus, system, and method described above further include a slurry introduction mechanism depositing a slurry on the upper surface of the polishing pad.

Some examples of the apparatus, system, and method described above further include a second motor coupled to the wafer carrier, the wafer carrier being configured to rotate in response to rotation of the second motor, wherein the first rotational axis and the second rotational axis are substantially parallel and non-coincident.

A method for chemical-mechanical polishing is described. One or more embodiments of the method include providing a first motor, providing a platen coupled to the first motor having a first rotational axis and a first diameter, and having a first circumference, providing a polishing pad on an upper surface of the platen, providing a wafer carrier, positioned adjacent to and above the polishing pad and configured to position a wafer over and in contact with the polishing pad, and having a second rotational axis and a second diameter that is smaller than the first diameter, wherein the first motor rotates the platen relative to the wafer carrier, providing a nozzle directed to an upper surface of the polishing pad, rotating, in response to rotation of the first motor, the platen, and supplying gas to the nozzle via a gas supply, wherein the nozzle directs a stream of the gas to the upper surface of the polishing pad.

An apparatus for chemical-mechanical polishing is described. The apparatus includes a processor, memory in electronic communication with the processor, and instructions stored in the memory. The instructions are operable to cause the processor to perform the steps of providing a first motor, providing a platen coupled to the first motor having a first rotational axis and a first diameter, and having a first circumference, providing a polishing pad on an upper surface of the platen, providing a wafer carrier, positioned adjacent to and above the polishing pad and configured to position a wafer over and in contact with the polishing pad, and having a second rotational axis and a second diameter that is smaller than the first diameter, wherein the first motor rotates the platen relative to the wafer carrier, providing a nozzle directed to an upper surface of the polishing pad, rotating, in response to rotation of the first motor, the platen, and supplying gas to the nozzle via a gas supply, wherein the nozzle directs a stream of the gas to the upper surface of the polishing pad.

A system for chemical-mechanical polishing is described. One or more embodiments of the system include providing a first motor, providing a platen coupled to the first motor having a first rotational axis and a first diameter, and having a first circumference, providing a polishing pad on an upper surface of the platen, providing a wafer carrier, positioned adjacent to and above the polishing pad and configured to position a wafer over and in contact with the polishing pad, and having a second rotational axis and a second diameter that is smaller than the first diameter, wherein the first motor rotates the platen relative to the wafer carrier, providing a nozzle directed to an upper surface of the polishing pad, rotating, in response to rotation of the first motor, the platen, and supplying gas to the nozzle via a gas supply, wherein the nozzle directs a stream of the gas to the upper surface of the polishing pad.

Some examples of the method, apparatus, non-transitory computer readable medium, and system described above further include providing a second nozzle directed to the upper surface of the polishing pad, wherein the gas supply is coupled to the second nozzle and the second nozzle directs another stream of the gas to the upper surface of the polishing pad.

In some examples, the supplying of the gas comprises supplying clean dry air.

In some examples, the supplying the gas comprises supplying pressurized nitrogen.

Some examples of the method, apparatus, non-transitory computer readable medium, and system described above further include providing a slurry introduction mechanism. Some examples further include depositing a slurry on the upper surface of the polishing pad.

Some examples of the method, apparatus, non-transitory computer readable medium, and system described above further include providing a second motor coupled to the wafer carrier. Some examples further include rotating the wafer carrier in response to rotation of the second motor, wherein the first rotational axis and the second rotational axis are substantially parallel and non-coincident.

Some of the functional units described in this specification have been labeled as modules, or components, to more particularly emphasize their implementation independence. For example, a module may be implemented as a hardware circuit comprising custom very large scale integration (VLSI) circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of executable code may, for instance, comprise one or more physical or logical blocks of computer instructions that may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of executable code could be a single instruction, or many instructions, and may even be distributed over several different code segments, among different programs, and across several memory devices.

Similarly, operational data may be identified and illustrated herein within modules, and may be embodied in any suitable form and organized within any suitable type of data structure. The operational data may be collected as a single data set, or may be distributed over different locations including over different storage devices, and may exist, at least partially, merely as electronic signals on a system or network.

While the invention herein disclosed has been described by means of specific embodiments, examples and applications thereof, numerous modifications and variations could be made thereto by those skilled in the art without departing from the scope of the invention set forth in the claims.

What is claimed is:

1. A system for polishing pad cooling in a wafer polishing apparatus, the system comprising:
a first motor;
a platen having a first rotational axis and being coupled to the first motor configured to rotate in response to rotation of the first motor;
a polishing pad on an upper surface of the platen;
a wafer carrier, positioned adjacent to and above the polishing pad and configured to position a wafer over and in contact with the polishing pad, and having a second rotational axis, wherein the first motor rotates the platen relative to the wafer carrier;
a nozzle directed to an upper surface of the polishing pad; and
a gas supply coupled to the nozzle configured to supply gas to the nozzle, wherein the nozzle directs a stream of the gas to the upper surface of the polishing pad.

2. The system of claim 1 comprising:
said platen having a first diameter, and having a first circumference; and
said wafer carrier having a second diameter that is smaller than the first diameter.

3. The system of claim 1 comprising:
another nozzle directed to the upper surface of the polishing pad, wherein the gas supply is coupled to the other nozzle, wherein the other nozzle directs another stream of the gas to the upper surface of the polishing pad.

4. The system of claim 1 wherein said gas is clean dry air.

5. The system of claim 1 wherein said gas is pressurized nitrogen.

6. The system of claim 1 further comprising:
a slurry introduction mechanism depositing a slurry on said upper surface of said polishing pad.

7. The system of claim 1 further comprising:
a second motor coupled to the wafer carrier, the wafer carrier being configured to rotate in response to rotation of the second motor, wherein said first rotational axis and said second rotational axis are substantially parallel and non-coincident.

8. A method for polishing pad cooling in a wafer polishing apparatus, the method comprising:
providing a first motor;
providing a platen coupled to the first motor having a first rotational axis and a first diameter, and having a first circumference;
providing a polishing pad on an upper surface of the platen;
providing a wafer carrier, positioned adjacent to and above the polishing pad and configured to position a wafer over and in contact with the polishing pad, and having a second rotational axis and a second diameter that is smaller than the first diameter, wherein the first motor rotates the platen relative to the wafer carrier;
providing a nozzle directed to an upper surface of the polishing pad;
rotating, in response to rotation of the first motor, the platen; and
suppling gas to the nozzle via a gas supply, wherein the nozzle directs a stream of the gas to the upper surface of the polishing pad.

9. The method of claim 8 comprising:
providing another nozzle directed to the upper surface of the polishing pad, wherein the gas supply is coupled to the other nozzle, wherein the other nozzle directs another stream of the gas to the upper surface of the polishing pad.

10. The method of claim 8 wherein said suppling of said gas comprises supplying clean dry air.

11. The method of claim 8 wherein said supplying said gas comprises supplying pressurized nitrogen.

12. The method of claim 8 further comprising:
providing a slurry introduction mechanism; and
depositing a slurry on said upper surface of said polishing pad.

13. The method of claim 8 further comprising:
providing a second motor coupled to the wafer carrier; and
rotating the wafer carrier in response to rotation of the second motor, wherein said first rotational axis and said second rotational axis are substantially parallel and non-coincident.
